(19) United States
(12) Patent Application Publication
(10) Pub. No.: US 2005/0255304 A1
(43) Pub. Date: Nov. 17, 2005

(54) Aligned nanostructure thermal interface material

(76) Inventor: Damon Brink, Goleta, CA (US)

Correspondence Address: MARK RODGERS, 1590 SAN ROQUE ROAD, SANTA BARBARA, CA, 93105, US

(21) Appl. No.: 11/126,813

(22) Filed: May 11, 2005

Related U.S. Application Data
(60) Provisional application No. 60/571,111, filed on May 14, 2004.

(51) Int. Cl. B32B 3/00; B32B 15/00; B32B 9/00; H01L 23/495

(52) U.S. Cl. 428/209; 427/180; 427/58; 427/532; 428/408; 257/675

(57) ABSTRACT

The invention relates to a thermal interface material comprising aligned nanostructures to increase the thermal conductivity of an electronic assembly. Aligned carbon nanotubes are a particularly suitable nanostructure possessing very high thermal conductivity. The novel use of nanostructures in the invention is particularly applicable to solving the issues of thermal expansion of the electronic assembly over time.

### RELATED APPLICATIONS

This application claims priority to provisional application 60/571,111, filed May 14, 2004

### FEDERALLY SPONSORED RESEARCH

Not Applicable

### SEQUENCE LISTING

Not Applicable

### BACKGROUND OF THE INVENTION

This invention relates to assemblies which transfer heat and contain an interface separating a “cold” side and a “hot” side.

The transfer of thermal energy is often a limiting performance factor for many engineering systems. The removal of waste heat from microprocessors is one example, and is quickly becoming one of the primary concerns facing the computer industry. The relevant aspects of heat transfer in computers are depicted in FIG. 1, a schematic of a typical “flip-chip” microprocessor configuration used in many desktop computers sold today. In this configuration, thermal energy generated by the microprocessor 11 is transferred to an integrated heat spreader 12 and subsequently to a heat sink 13 that is cooled by forced convection within the computer housing. The heat spreader increases the amount of thermal flux that can be extracted by the system by increasing heat flow tangential to the microprocessor, in turn making the distal portions of the heat sink 14 more effective. The dark arrows 17 in the figure depict the direction of thermal flux and show the spreading phenomenon. The heat spreader also serves to protect the microprocessor during transport and assembly.

The transfer of heat from the microprocessor to the heat spreader itself involves an interface. The contact resistance associated with the interface is responsible for a majority of the thermal resistance in this portion of the assembly. The large thermal resistance is due to the lack of intimate contact between surfaces on a small scale. In other words, asperities on the surfaces of the heat spreader and microprocessor result in the formation of small air gaps which act as thermal insulators. The actual amount of true contact area between the surfaces is quite small, severely restricting the flow of thermal energy across the interface.

The use of a thermal interface material (TIM) greatly enhances thermal transfer across the mated surfaces of two materials by wetting both surfaces and substantially reducing the amount of air trapped on the interface. In FIG. 1, TIM 1 15 thermally connects the microprocessor (aka die) 11 to the heat spreader 12, and TIM 2 16 marries the heat spreader to the surface of the heat sink 13. A typical TIM material is shown in FIG. 2, an enlarged view of the highlighted area of TIM 1 18 in FIG. 1. Thermal interface materials typically consist of greases, silicones, gels, and phase change materials which serve as a matrix 31, and a second phase of higher thermal conductivity that serves as a filler 32. The matrix material, i.e. grease, is then able to fill-in the asperities along the surface of the microprocessor 33 and integrated heat spreader 34, while the filler helps to increase thermal conductivity in the TIM itself. The distance between 33 and 34 is known as the bond-line thickness (BLT). The general direction of thermal transfer is depicted by the dark arrows in the microprocessor 35 and the heat spreader 36.

FIG. 3 depicts the interface between the microprocessor and heat spreader 33 on a small scale and reveals a typical interfacial morphology. First, the TIM 15 and the microprocessor 11 are joined by the interface 33. The surface of the microprocessor can be rough on this length scale, resulting the jagged appearance that can result in trapped air pockets 54, 55 near the more extreme asperities. It is a goal of thermal interface materials to wet the surface and minimize the number of air-gaps that form during assembly. The thermal interface material itself consists of a grease or polymer matrix 31 and a filler 32. The size scale of the filler in most TIMs is larger than the air pockets which form on the interface due to micro-asperities. The filler is a material with a larger thermal conductivity than the matrix, and improves overall conductivity of the TIM as heat is transferred from the matrix to the higher thermal conductivity particles. The interface between the particle filler and the TIM matrix must be free of air gaps for effective operation. It is thus another objective of thermal interface materials to contain filler materials that are wet by the matrix. The multiple interfaces between filler and matrix through the thickness of the TIM, however, greatly increases the bulk thermal resistance of the TIM.

Although the use of thermal interface materials substantially decreases the thermal interface resistance, it remains the largest portion of the overall thermal resistance and continues to pose a problem to next generation chip sets which will generate higher thermal loads. Thus, there is a need within the industry to develop more effective thermal interface materials and new heat transfer methodologies.

Due to the thermal expansion of the various components within the flip-chip configuration depicted in FIG. 1, other aspects of the microprocessor “package” become important to thermal transfer across the interface due to an interaction with geometry and the thermal interface materials. The other salient components in FIG. 1 include the ball grid array (BGA) 19, the underlying printed circuit board (PCB) 20, and the adhesive interface between the heat spreader and the PCB 21. Briefly, the BGA electrically connects the microprocessor to the PCB, and the adhesive 21 physically attaches the heat spreader to the PCB. The later is important for maintaining close contact between the microprocessor and heat spreader, as thermal interface materials, in general, are not necessarily formulated to be good adhesives themselves.

During operation, the various components in the package heat up and expand according to their unique thermal expansion coefficients. As the thermal expansion coefficients of the components are not all equal, mismatch along the interfaces can occur and results in shearing of the thermal interface material. The amount of strain or displacement mismatch that occurs depends on the size of the components, the material from which they are fabricated, and the change in temperature during operation. These factors can result in large relative displacements between the edge of the microprocessor and the heat spreader. If the thermal interface material cannot accommodate these displacements, large stresses at the interface can result and cause failure along the interface or within the microprocessor. It is thus a requirement that thermal interface materials in classical designs are compliant and can flow (plastic strain) under the induced displacement.

The thermal expansion mismatch can also cause a phenomenon called “pump-out” wherein the thermal interface material is extruded from the edge of the interface through repeated thermal cycling. Pump-out is caused from a change in the bond-line thickness of the thermal interface that results from distortion of the interface. This distortion is a direct result of the forces caused by thermal expansion, primarily between the PCB and heat spreader. Briefly, the heat spreader expands more than the PCB during operation and is also constrained by the adhesive locations 21, causing the heat spreader to bow. The repeated change in TIM volume due to this distortion can result in pump- out. It is thus advantageous that thermal interface materials be able to withstand these distortions and not irreversibly flow away from the interface.

The thermal conductivity across the interface can be greatly improved by attaching the surfaces with a solder bond or other metal attach. Such a strategy is shown in FIG. 4, wherein the microprocessor 11 is attached to the surface of the heat spreader 12 via an interposed metal layer 73 that is metallurgically bonded to both surfaces. In this figure, the PCB 20 and direction of heat flow 75 are also shown. The aforementioned thermal expansion can present a large problem with metal attach, however. The large cyclic stresses that can develop often results in thermomechanical fatigue of the metal interlayer, causing the formation of cracks 76 which degrade thermal performance with time resulting in package failure.

Packaging and assembly of the integrated heat spreader and heat sink also presents challenges to the microprocessor industry. Presently, thermal interface materials in the form of a paste are applied to the die prior to attaching the integrated heat spreader. The thermal interface material used to attach the heat sink is applied in a separate operation. There are often problems with dispensing the paste for TIM 1 that can result in unacceptable variation in the ultimate thermal performance of the assembly. In addition, there are commonly gaps on the interface that is joined with the paste that act to decrease the heat-carrying capacity of the system. Thus, there is a need within the industry to provide a method of joining the die, heat spreader, and heat sink that requires fewer processing steps, is a more robust process with respect to variation in ultimate thermal performance, and results in an interface that contains fewer voids.

### SUMMARY OF THE INVENTION

In one embodiment, the invention is a thermal interface material for an electronic assembly which includes aligned conductive structures spanning a bondline between two surfaces and a matrix material as a wetting and support agent for the conductive structures. In one version, the conductive structures are aligned with an electric field.

In another embodiment, the thermal interface material includes aligned conductive structures spanning a bondline between two surfaces and the conductive structures are overlapped such that wider bondlines may be spanned. In a version the thermal interface material also includes a matrix material as wetting and support agent for the conductive structures. In an aspect, the conductive structures are aligned with an electric field.

In another embodiment, the invention is a thermal interface material for an electronic assembly including aligned conductive structures spanning a bondline between two surfaces such that the conductive structures are longer than the width of the bondline. In one version the conductive structures are bent in contact on one surface. In some aspects the material may include a matrix material as wetting and support agent for the conductive structures and the carbon conductive structures may be aligned aligned with an electric field.

In a further embodiment, the invention is a heat spreader for an electronic assembly including at least one surface, aligned conductive structures deposited on at least one surface and, a matrix material as a wetting and support agent for the conductive structures.

In another embodiment, the invention is a method of making a thermal interface material for an electronic assembly including depositing conductive structures on a surface, embedding the conductive structures in a matrix material and, aligning the conductive structures using an electric field. In one version, the conductive structures overlap along their length allowing for wider gaps to be spanned. In another version, the conductive structures are longer than the gap to be spanned to allow for thermal expansion and contractions. In a version the number of internal interfaces between the matrix and conducting structures is four or fewer. In another, the number of internal interfaces between the matrix and conducting structures is two or fewer. In all the above embodiments, the conductive structures may be, but not limited to, carbon nanotubes, silver carbon nanotubes, silver nanofibers, or aligned contiguous conductive particles, and matrix material may be, but not limited to thermal grease, silicone, gels, or phase change material.

### BRIEF DESCRIPTION OF THE DRAWINGS

The invention will better understood by referring to the included drawings

FIG. 1 is a plan view of a microprocessor package, depicting the relative locations of the microprocessor, integrated heat spreader, and the heat sink.

FIG. 2 is an enlarged view of a typical thermal interface material (TIM) and the surrounding interfaces.

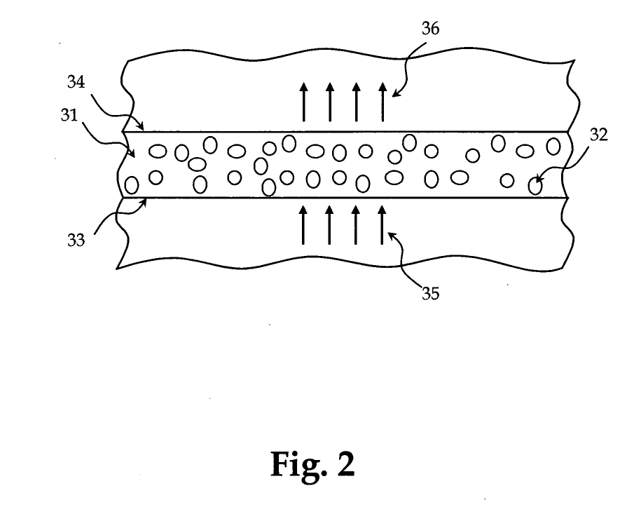

FIG. 3 is an enlarged view of an interface formed between the TIM and microprocessor, depicting the small surface asperities which can inhibit contact between surfaces and trap air.

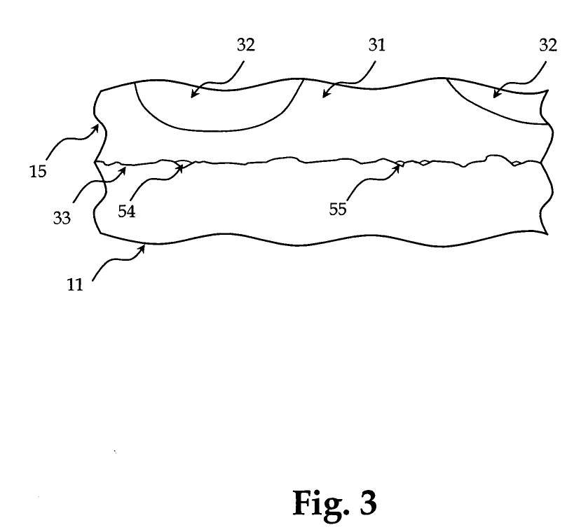

FIG. 4 is an enlarged view of the microprocessor and contact region with the heat spreader. These components are connected with a metal interlayer which can develop fatigue cracks due to the thermomechanical stresses that form during operation.

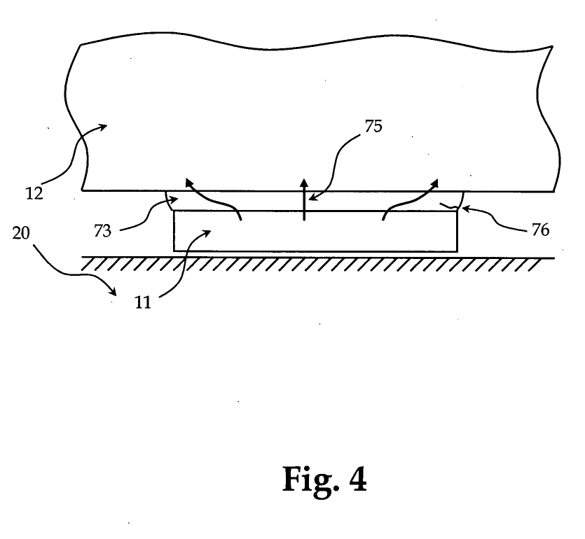

FIG. 5 is an enlarged view of the interface between the die and the heat spreader that contains a thermal interface material comprising carbon nanotubes that bridge a substantial portion of the bond line thickens.

FIG. 6 is a close-up of an interface between a substrate and the TIM containing carbon nanotubes.

FIG. 7 depicts the growth mechanism of carbon nanotubes on the surface of a substrate using a chemical vapor deposition technique.

FIG. 8 depicts deposition of carbon nanotubes such that they overlap along their length

FIG. 9 shows a method by which the thermal transfer across an interface can be increased by bending the distal ends of carbon nanotubes and increasing the surface area contacting the substrate.

FIG. 10 depicts an interface wherein the ends of carbon nanotubes are chemically bonded to a substrate.

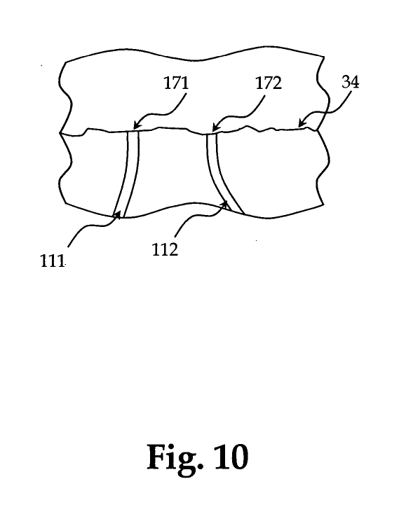

### DETAILED DESCRIPTION

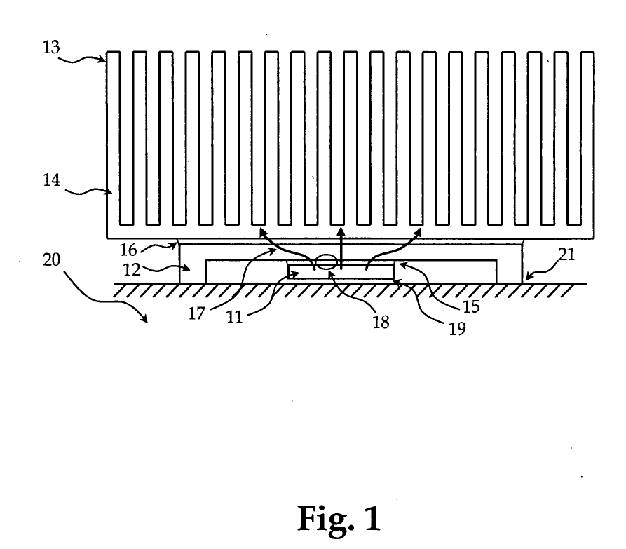

FIG. 1 depicts a typical thermal packaging solution for a microprocessor used on a desktop computer. In this “flip-chip” configuration, the relevant components include the microprocessor 11, an integrated heat spreader 12, a heat sink 13, the interfaces between these components 15, 16, and the printed circuit board (PCB) substrate 20. Heat generated by the microprocessor during operation is conducted into the heat spreader 12 and subsequently into the heat sink 13 via the interfaces separating these components.

Continued increases in the processing power of the microprocessor may become limited by the ability to disperse heat, and it is thus beneficial to have a low thermal resistance between the microprocessor and the heat sink. The overall thermal resistance of the package is dominated by the resistance of the interfaces 15, 16, and large performance gains can be realized if the contact resistance associated with these interfaces can be reduced. Although the interfacial contact resistance can be significantly reduced with the use of thermal interface material, the performance of the present TIMs will not satisfy the heat dissipation requirements of next- generation microprocessors. There is thus a need within the thermal packaging industry to develop more effective thermal interface materials that will satisfy these increasing thermal loads.

Typical thermal interface materials consist of a matrix (polymer, grease, or gel) and high-conductivity filler. The fillers are typically metals such as silver or aluminum, or highly conductive ceramics such as boron nitride. The highest conductivity filler used in conventional thermal interface materials—silver—has a thermal conductivity of approximately 429 W/mK. Even with relatively large volume fractions of filler, however, the bulk conductivity of these TIM materials rarely exceeds 10 W/mK. The severe degradation between the filler conductivity and the actual value of the bulk material stems from the multiple interfaces between the particulate filler and matrix. Depending on the particle size, shape, and bond line thickness, there can be hundreds of such interfaces along the thermal path of the TIM.

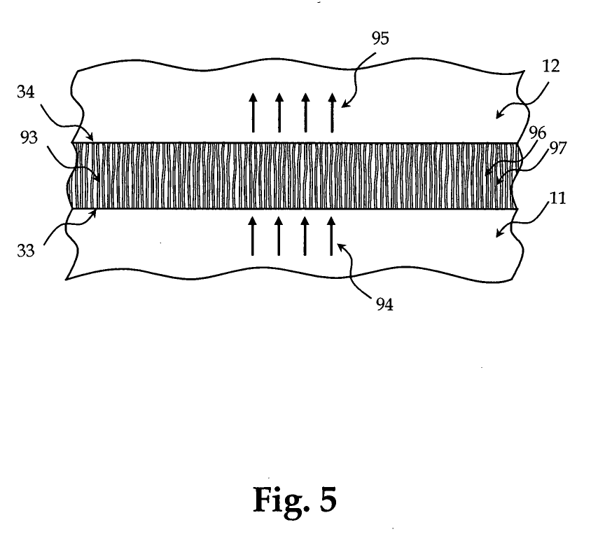

In an embodiment of the present invention, a thermal interface material is created such that the number of matrix-filler interfaces along the thermal path is reduced to two, substantially increasing the effective (bulk) thermal conductivity of the TIM. This is accomplished by aligning highly conductive nanostructures, e.g. carbon nanotubes, such that they span the entire bond line thickness. The structure of such a thermal interface material is depicted in FIG. 5. Here, the “hot” interface 33 on the die 11 is connected to the “cold” interface 34 on the integrated heat spreader 12 via an array of carbon nanotubes 93. The direction heat flow before and after the interface is shown by the arrows 94, 95. In this embodiment, once thermal energy is transferred to one end of the carbon nanotube, it can travel the entire distance of the bond line along the same contiguous structure, without encountering additional interfaces which would severely degrade thermal transfer performance. Single-walled carbon nanotubes, multi-walled carbon nanotubes, or a combination thereof can be used. Other structures such as silver nanofibers, aligned and contiguous particles, or other conductive media can also be used in this manner. In the case of the carbon nanotubes, however, bulk thermal conductivities are expected to be superior as the estimated thermal conductivity of the nanotubes themselves range from 3,000 to 6,000 W/mK. Typical bond-line thicknesses range between 0.0005″ to 0.005″, with the larger BLT's being more common for higher volume operations wherein manufacturing costs are a large concern. Thus, the length of the nanotubes must range between 0.0005″ and 0.005″ to fully span the interface. Wetting of the interfaces is accomplished with a thermal grease that also fills the gaps between nanotubes 96, 97 and acts to support the structures. The alignment of the nanostructures can be accomplished by exposing the TIM to a strong electric field, a well-known technique.

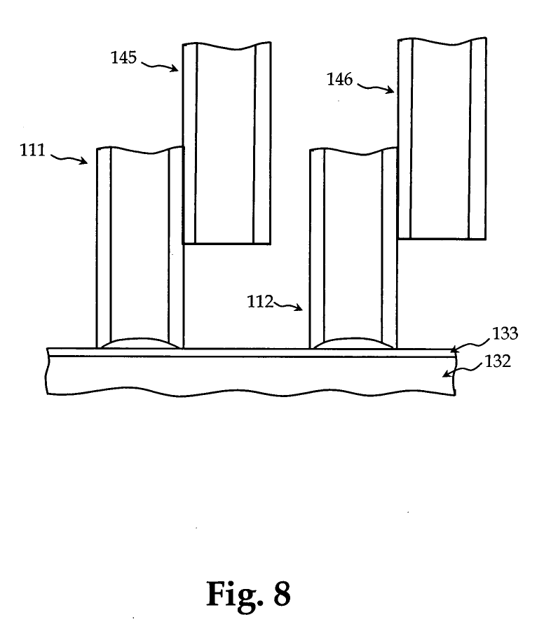

Another embodiment takes advantage of the substantial overlap between aligned carbon nanotubes or other structures. This is depicted in FIG. 8 where nanotubes 145 and 146 overlap tubes 111 and 112 repsectively. In this case, the thermal energy traveling up one carbon nanotube can be transferred to another via lateral heat transfer from tube to tube. The rate of heat transfer in this direction is substantially less for carbon nanotubes. In addition, there is an additional interface resistance which limits heat flow in this direction. The result is that this mode of conduction is less effective than a continuous carbon nanotube, and requires a large overlap of the tubes to make the mechanism viable. Nevertheless, this embodiment represents a large performance improvement over conventional thermal interface materials.

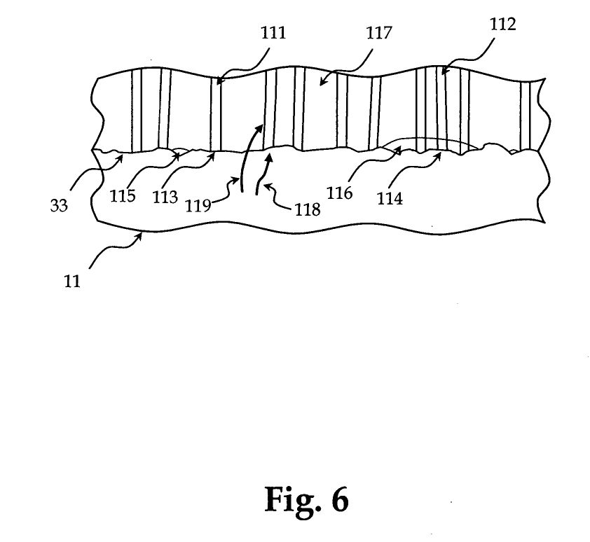

In another preferred embodiment, the ends of the carbon nanotubes are physically attached to one interface, ensuring intimate contact and excellent thermal transfer between the substrate and base of the carbon nanotube. This strategy effectively eliminates one thermal interface and will decrease overall thermal resistance. The relevant configuration on the size scale of the nanotube diameter is shown in FIG. 6. In keeping with previously established orientations, individual carbon nanotubes 111, 112 are connected to the die 11 via intimate attachment at the interface 33 in specific areas 113, 114. Note that the carbon nanotubes can also be attached to the surface of the heat spreader. On this length scale, the surface roughness and small pockets of air 115, 116 not wetted by the thermal grease are evident. The deleterious influence of air pockets on the interfacial heat transfer is minimized due to the physical attachment of the nanotube itself. In other words, the nanotubes can bridge the air gaps as depicted for tube 112. Consistent with previous descriptions, the carbon nanotubes are surrounded by a thermal grease 117 that supports the nanostructures and helps to transfer heat to the tubes. Thus, direct thermal conduction into the nanotube end 118 is augmented by initial conduction into the thermal grease and subsequently into the nanotube wall 119.

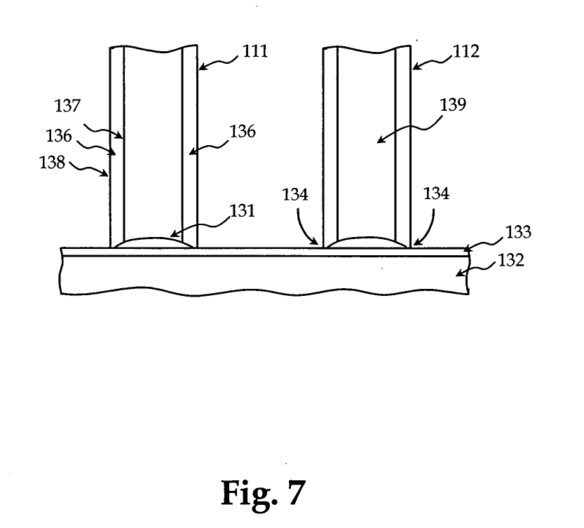

FIG. 7 shows a potential carbon nanotube growth and attachment mechanism. The nanotubes grow from the interaction between a carbon-containing atmosphere and a catalyst 131 deposited on the surface 132 intended to harbor the nanotubes. The surface may be that of the die or heat spreader, and may contain an additional plating or coating 133, such as a Ni plating used to protect a copper heat spreader from corrosion. The flux of carbon from the atmosphere 134 results in the formation and growth of the nanotubes 135. FIG. 7 depicts a cross section of the carbon nanotubes, wherein the walls are delineated by an inner surface 137 and an outer surface 138 and contain a hollow core 139. Depending on the growth conditions, the walls may consist of one or more layers of carbon chains. Due to the high temperatures required for the chemical vapor deposition and growth of carbon nanotubes, these processes are best performed on the heat spreader interface to avoid thermally degrading the active elements of the die.

Heat transfer between the carbon nanotube and an interface may also be addressed by allowing a significant portion of the nanotube to be bent such that it maintains a close proximity to the interface over a large portion. Such a condition is depicted in FIG. 8. In this embodiment, the nanotubes 111, 112 are longer than the bond line thickness and forced to deform at the ends to accommodate the solid surface 154. The bent end of the nanotube 151 results in a longer contact length for each nanotube, spanning from the root of the bend 152 to the tip of the nanotube 153. The increased contact length can be the equivalent of many tube diameters, greatly increasing the flow of thermal energy between the nanotubes and the interface. The carbon nanotubes may protrude from the matrix material to allow a sharp bend near the interface when the opposing solid interface is brought into contact with TIM. Alternatively, the mating surface may be actuated ultrasonically or in an oscillatory motion that is lateral to the nanotube direction. This type of motion will result in localized bending of the nanotubes near the interface.

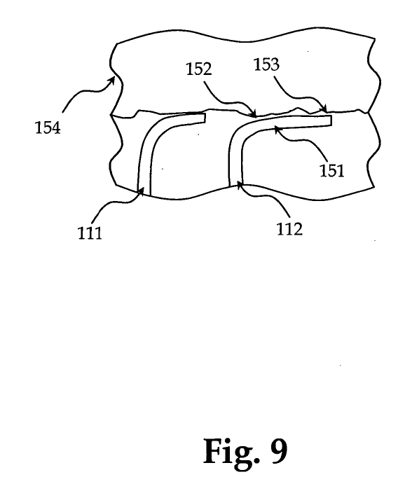

In another embodiment, the ends of the carbon nanotubes can be bonded to the interfaces after growth. Such a situation is depicted in FIG. 9, wherein two nanotubes 111, 112 are securely bonded to the interface of the integrated heat spreader. This structure can be achieved by bonding silanes to the end of the carbon nanotubes, and subsequently bonding the silanes to the substrate surface 171, 172. When both ends of the tubes are bonded, the interface contact resistance is greatly decreased, as discussed previously. However, to allow for thermal expansion, at least a portion of the nanotubes must be longer than the bond line thickness to accommodate the cyclic strain.

Another embodiment includes carbon nanotubes grown on both sides of an integrated heat spreader and infiltrated with a thermal grease or other appropriate matrix material. This provides a superior thermal interface material for both TIM 1 and TIM 2 and reduces the number of manufacturing steps.

While the invention has been particularly shown and described with reference to preferred embodiments thereof, it will be understood by those skilled in the art that the foregoing and other changes in form and detail may be made therein without departing from the scope of the invention.

1. A thermal interface material for an electronic assembly, comprising;
aligned conductive structures spanning a bondline between two surfaces; and,
a matrix material as a wetting and support agent for the conducting structures.

2. The thermal interface material of claim 1 wherein the conductive structures are aligned with an electric field.

3. The thermal interface material of claim 1 wherein the conductive structures are at least one of carbon nanotubes, silver nanofibers, or aligned contiguous conductive particles.

4. The thermal interface material of claim 1 wherein the matrix material is at least one of thermal grease, silicone, gels, or phase change material.

5. A thermal interface material for an electronic assembly, comprising aligned conductive structures spanning a bondline between two surfaces wherein the conductive structures are overlapped such that wider bondlines may be spanned.

6. The thermal interface material of claim 5 further comprising a matrix material as wetting and support agent for the carbon conducting structures.

7. The thermal interface material of claim 5 wherein the conducting structures are aligned with an electric field.

8. The thermal interface material of claim 5 wherein the conductive structures are at least one of carbon nanotubes, silver nanofibers, or aligned contiguous conductive particles.

9. The thermal interface material of claim 5 wherein the matrix material is at least one of thermal grease, silicone, gels, or phase change material.

10. A thermal interface material for an electronic assembly, comprising aligned conductive structures spanning a bondline between two surfaces wherein the conductive structures are longer than the width of the bondline.

11. The thermal interface material of claim 10 wherein the conductive structures are bent in contact on one surface.

12. The thermal interface material of claim 10 further comprising a matrix material as wetting and support agent for the conducting structures.

13. The thermal interface material of claim 6 wherein the carbon conducting structures are aligned with an electric field.

14. The thermal interface material of claim 10 wherein the conductive structures are at least one of carbon nanotubes, silver nanofibers, or aligned contiguous conductive particles.

15. The thermal interface material of claim 10 wherein the matrix material is at least one of thermal grease, silicone, gels, or phase change material.

16. A heat spreader for an electronic assembly, comprising;
at least one surface, aligned conducting structures deposited on at least one surface; and,
a matrix material as a wetting and support agent for the conducting structures.

17. The heat spreader of claim 16 wherein the conductive structures are at least one of carbon nanotubes, silver nanofibers, or aligned contiguous conductive particles.

18. The heat spreader of claim 16 wherein the matrix material is at one of least thermal grease, silicone, gels, or phase change material.

19. A method of making a thermal interface material for an electronic assembly, comprising;
depositing conducting structures on a surface,
embedding the conducting structures in a matrix material; and,
aligning the conducting structures using an electric field.

20. The method of claim 19 further comprising depositing conducting structures the overlap along their length allowing for wider gapes to be spanned.

21. The method of claim 19 wherein the conducting structures are longer than the gap to be spanned to allow for thermal expansion and contractions.

22. The method of claim 19 wherein the conductive structures are at least one of carbon nanotubes, silver nanofibers, or aligned contiguous conductive particles.

23. The thermal interface material of claim 19 wherein the matrix material is at least one of thermal grease, silicone, gels, or phase change material.

24. The thermal interface material of claim 19 wherein the number of internal interfaces between the matrix and conducting structures is four or fewer.

25. The thermal interface material of claim 19 wherein the number of internal interfaces between the matrix and conducting structures is two or fewer.
